(19) United States
(12) Patent Application Publication
(10) Pub. No.: US 2025/0266409 A1
(43) Pub. Date: Aug. 21, 2025

(54) ISOLATOR

(71) Applicants: Kabushiki Kaisha Toshiba, Tokyo (JP); Toshiba Electronic Devices & Storage Corporation, Tokyo (JP)

(72) Inventors: Itsuki MATSUO, Kawasaki Kanagawa (JP); Eitaro MIYAKE, Tachikawa Tokyo (JP); Yuusuke IMAIZUMI, Kawasaki Kanagawa (JP); Jia LIU, Yokohama Kanagawa (JP); Yoshinari TAMURA, Yokohama Kanagawa (JP)

(21) Appl. No.: 18/815,554

(22) Filed: Aug. 26, 2024

(30) Foreign Application Priority Data
Feb. 15, 2024 (JP) 2024-020877

(51) Int. Cl. H01L 25/16; H01F 27/28; H01L 23/00; H01L 23/31; H01L 23/498; H01L 23/538

(52) U.S. Cl. CPC H01L 25/16; H01F 27/2804; H01L 23/5385; H10D 1/20; H01L 23/3107; H01L 23/49811; H01L 24/16; H01L 2224/16227

(57) ABSTRACT

According to one embodiment, an isolator device includes a rigid substrate and a flexible printed circuit board stacked on the rigid substrate in a first direction. A first coil is in the flexible printed circuit board. A second coil is also in the flexible printed circuit board, but spaced from and aligned with the first coil in the first direction. A first semiconductor chip is connected to the first coil by a first wiring. A second semiconductor chip is connected to the second coil by a second wiring.

### CROSS-REFERENCE TO RELATED APPLICATION

This application is based upon and claims the benefit of priority from Japanese Patent Application No. 2024-020877, filed Feb. 15, 2024, the entire contents of which incorporated herein by reference.

### FIELD

Embodiments described herein relate generally to an isolator for permitting signal transmission between electrically insulated circuits, devices, or the like.

### BACKGROUND

Isolators permitting the transmitting of a signal from a transmitter circuit to a receiver circuit that are electrically insulated from each other are known. Some such isolators use a light emitting element and a light receiving element but there are also isolators using wiring coils or the like.

### BRIEF DESCRIPTION OF THE DRAWINGS

FIG. 1 is a schematic plan view illustrating an isolator according to a first embodiment.

FIG. 2 is a schematic view illustrating an isolator according to the first embodiment.

FIG. 3 is a cross-sectional illustrating an isolator according to a first embodiment.

FIG. 4 is a cross-sectional view illustrating an example of an internal structure of a flexible printed circuit.

FIG. 5 is a cross-sectional view illustrating an isolator according to a modification example of a first embodiment.

FIG. 6 is a cross-sectional view illustrating an isolator according to a second embodiment.

FIG. 7 is a cross-sectional view illustrating an isolator according to a third embodiment.

FIG. 8 is a cross-sectional view illustrating an isolator according to a modification example of a third embodiment.

FIG. 9 is a cross-sectional view illustrating an isolator according to a fourth embodiment.

### DETAILED DESCRIPTION

Example embodiments relate to an isolator having improved reliability.

In general, according to one embodiment, an isolator device includes a first rigid substrate and a flexible printed circuit board stacked on the first rigid substrate in a first direction. A first coil is in the flexible printed circuit board. A second coil is also in the flexible printed circuit board, but spaced from and aligned with the first coil in the first direction. A first semiconductor chip is connected to the first coil by a first wiring. A second semiconductor chip is connected to the second coil by a second wiring.

According to another embodiment, an isolator device includes a first die pad, a first semiconductor chip on the first die pad, a second die pad spaced from the first die pad, and a substrate on the second die pad. The substrate includes a first rigid substrate and a flexible printed circuit board stacked on the first rigid substrate in a first direction. A first coil is in the flexible printed circuit board. A second coil is also in the flexible printed circuit board but spaced from and aligned with the first coil in the first direction. An electrode pad is on an upper surface of substrate and electrically connected to the second coil. A third die pad is spaced from the first die pad and the second die pad in a second direction intersecting the first direction. A second semiconductor chip is on the third die pad. A first wire electrically connects the first semiconductor chip to the second die pad, and a second wire electrically connects the electrode pad to the second semiconductor chip.

Hereinafter, certain example embodiments will be described with reference to the drawings.

In general, the drawings are schematic or conceptual, and as such the depicted dimensions and dimensional relationships between such things as component thicknesses, widths and the like are not necessarily those in an actual implementation but rather selected for descriptive clarity or convenience. Similarly, the depicted ratios between the sizes of different components, and the like are not necessarily the same as actual ones in an implementation of the present disclosure. In addition, even when the same component is illustrated in different drawings, its dimensions and relative sizing may vary drawing to drawing.

For example, some cross-sectional views in the present specification illustrates a stacked structure. In this case, a ratio between the thicknesses of the layers in the stacked structure is not necessarily the same as the actual one. Even when one layer is shown as thicker than another layer in the cross-sectional view, the different layers may have the same thickness or the reverse sizing relationship may be adopted. That is, any dimension such as a thickness illustrated in the drawings may be different from an actual one.

Orthogonal coordinate axes may be depicted in the drawings such that the X direction, the Y direction, and the Z direction are indicated, but such depictions are for purposes of descriptive convenience and no orientation or specific relationship between necessarily to be implied unless otherwise stated.

In addition, for convenience in description, a positive direction along the Z direction may be referred to as an “upper” or “upward” direction, and a negative direction along the Z direction may be referred to as a “lower” or “downward” direction. It should be noted that the “upper” and “lower” directions are not limited to the gravity direction or directions or orientations adopted during mounting of a semiconductor device to a substrate, board, or the like.

In the present specification and each of the drawings, those elements that are the same (or substantially so) as those already described by reference to a previous drawing are represented by the same reference symbols, and the detailed description thereof may not be repeated.

### First Embodiment

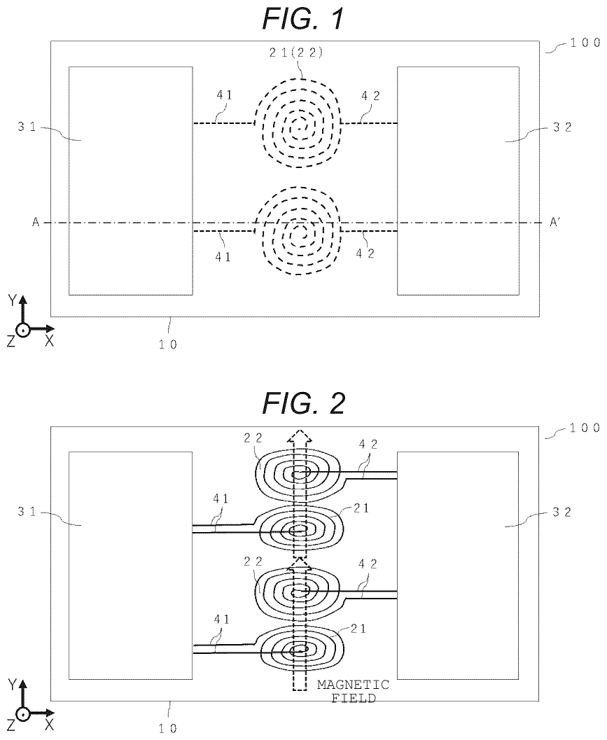

FIG. 1 is a schematic plan view illustrating an isolator 100 according to the first embodiment.

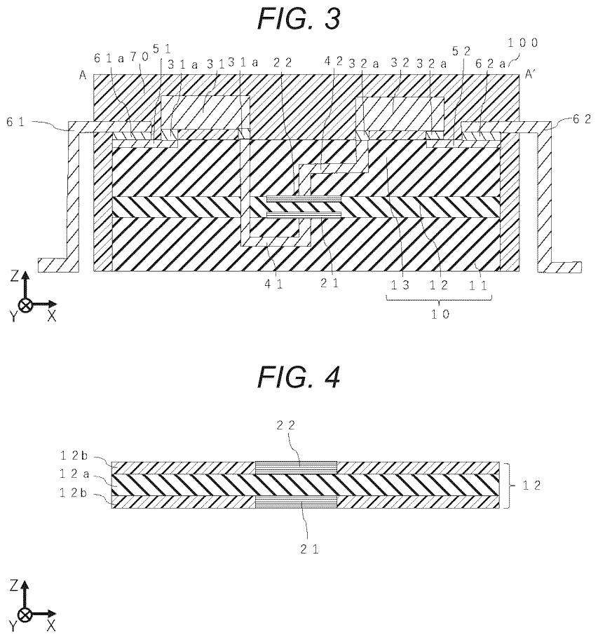

The isolator 100 includes a substrate 10, a first semiconductor chip 31, a first wiring 41, a first coil 21, a second coil 22, a second wiring 42, and a second semiconductor chip 32. These members are covered with a resin portion 70 (see FIG. 3). The isolator 100 is, for example, a semiconductor package or a packaged semiconductor device.

FIG. 1 does not illustrate external connection terminals that are connected to the first semiconductor chip 31 and the second semiconductor chip 32, but see FIG. 3 below, the isolator 100 includes lead frames 61 and 62 as terminals.

A plurality of coils is provided in substrate 10. These coils include a first coil 21 and a second coil 22 provided in the substrate 10. Each of the coils has, for example, a spiral shape in a plan view. The second coil 22 is disposed above (the positive direction of the Z direction) the first coil 21 and is spaced (separated) from the first coil 21 in the Z direction. In FIG. 1, the first coil 21 and the second coil 22 overlap each other. A first coil 21 and a second coil 22 are provided to be a magnetically coupled pair.

In the example illustrated in FIG. 1, two first coils 21 and two second coils 22 are depicted. However, the number of first coils 21 and second coils 22 are not limited to the example illustrated in FIG. 1 and any number of one or more may be provided.

The first wiring 41 electrically connects the first semiconductor chip 31 to the first coil 21. The second wiring 42 electrically connects the second semiconductor chip 32 to the second coil 22.

FIG. 2 is a schematic view illustrating the isolator 100 according to the first embodiment. Unlike FIG. 1, to illustrate the presence and relationship of the first coils 21 and the second coils 22, which overlap each other in plan view, the coils are illustrated in a tilted (non-plan view) manner to permit easier description of certain aspects.

The first wiring 41 is provided between the first semiconductor chip 31 and the first coil 21. For example, a plurality of the first wirings 41 are formed with one first wiring 41 connected to a center portion and another first wiring 41 connected to an outer edge portion of the first coil 21. Here, regarding the center portion and the outer edge portion of the coil, for example, a portion including one end of the coil (obtained by forming a conducting wire in a spiral shape) is defined as the center portion, and a portion including the opposite end of the coil is defined as the outer edge portion. An electrical signal can be transmitted from the first semiconductor chip 31 to the first coil 21 through the first wiring 41. In this context, the electrical signal refers to a direction or a magnitude of a current through the first coil 21 or a change over time in the magnitude of a current in the first coil 21.

FIG. 2 illustrates an example where the isolator 100 includes two first coils 21 and two second coils 22. Each of the second coils 22 is disposed above a first coil 21. The second coil 22 and the second semiconductor chip 32 are electrically connected to each other through a second wiring 42. For example, a plurality of the second wirings 42 are formed, and one second wiring 42 is connected to a center portion of the second coil 22 and another second wiring 42 is connected to an outer edge portion of the second coil 22.

The first coil 21 and the second coil 22 being magnetically coupled refers to a magnetic field generated by a current flowing through the first coil 21 interacts with the second coil 22 such that a current flows through the second coil 22 by electromagnetic induction. In FIG. 2, the upward arrows indicate the magnetic field in the positive Z direction generated by the first coil 21. Since the second coil 22 is provided above the first coil 21, the magnetic field (arrow) illustrated in the drawing passes through the second coil 22.

Next, an operation of the isolator 100 will be described with reference to FIG. 2. The described example the first semiconductor chip 31 is an input side and the second semiconductor chip 32 is an output side. The isolator 100 transmits a signal from the first semiconductor chip 31 to the second semiconductor chip 32, the first and second semiconductor chips 31 and 32 are electrically insulated from each other. First, when an input signal flows through the first semiconductor chip 31, the input signal flows to the first coil 21 through the first wiring 41. The current flowing through the first coil 21 generates a magnetic field as illustrated in FIG. 2.

The second coil 22 is spaced from the first coil 21, and an insulator material is interposed between the first coil 21 and the second coil 22 in the Z direction. That is, in general, an electrical potential of the first coil 21 and an electrical potential of the second coil 22 can be different from each other. However, the generated magnetic field can pass through the insulator material to reach the second coil 22 from the first coil 21. Since the magnetic field passes through the second coil 22, an induced current flows through the second coil 22.

The current flowing through the second coil 22 then reaches the second semiconductor chip 32 through the second wiring 42. In this way, an electrical signal is transmitted from the first semiconductor chip 31 to the second semiconductor chip 32.

FIG. 3 is a cross-sectional view illustrating an example of a cross-sectional structure of the isolator 100. FIG. 3 is a cross-sectional view taken along line A-A′ of FIG. 1.

As illustrated in FIG. 3, the isolator 100 includes a substrate 10, a first coil 21, a second coil 22, a first semiconductor chip 31, a second semiconductor chip 32, a first wiring 41, a second wiring 42, conductive layers 51 and 52, lead frames 61 and 62, and a resin portion 70. A part of the lead frames 61 and 62 protrudes from the resin portion 70 and can be used as an external connection terminal of the isolator 100.

The substrate 10 has a first rigid substrate 11, a first flexible printed circuit 12 (first flexible circuit substrate), and a second rigid substrate 13 stacked one on the other. The first flexible printed circuit 12 is provided on the first rigid substrate 11. The second rigid substrate 13 is provided on the first flexible printed circuit 12. However, a configuration where planar members are simply stacked on each other is not a limitation and any configuration where coil members or the like can be arranged overlap each other in the Z direction can be adopted.

The first rigid substrate 11 and the second rigid substrate 13 are, for example, rigid circuit substrates comprising an epoxy resin, such as a printed circuit board or the like. The first flexible printed circuit 12 is, for example, a flexible printed circuit board (also referred to as a FPC board) that comprises a film material such as a polyimide or a liquid crystal polymer. The first flexible printed circuit 12 is formed, for example, on a film, such as a polyimide film or a polyethylene terephthalate (PET) film, as a base or substrate. Wiring and/or other circuit elements may be provided on the film. The first flexible printed circuit 12 can be any substrate material or the like having a lower stiffness than the first rigid substrate 11 and the second rigid substrate 13.

The first flexible printed circuit 12 is provided between the first rigid substrate 11 and the second rigid substrate 13. The first printed circuit 12 has a conductive material on both surfaces in the up-down direction (Z direction). The conductive material forms a coil on each surface. As illustrated in FIG. 3, the first coil 21 is formed on a lower surface side of the first flexible printed circuit 12, and the second coil 22 is formed on an upper surface side of the first flexible printed circuit 12.

The first coil 21 and the second coil 22 are spaced from each other and face each other in the Z direction. The internal structure of the first flexible printed circuit 12 will be described below with reference to FIG. 4.

Electrical connection between the first semiconductor chip 31 and the first wiring 41 and electrical connection between the first semiconductor chip 31 and the conductive layer 51 can be ensured by an adhesive layer 31a. FIG. 3 illustrates an example where each of the first semiconductor chip 31 and the second semiconductor chip include a plurality of electrodes on a lower surface. A plurality of adhesive layers 31a or 32a are respectively connected to different electrodes.

The conductive layer 51 is electrically connected to the lead frame 61 through an adhesive layer 61a. The adhesive layer 31a and 61a can be, for example, a solder or a silver paste.

An adhesive layer 32a provides electrical connection between the second semiconductor chip 32 and the second wiring 42 and electrical connection between the second semiconductor chip 32 and the conductive layer 52. In addition, the conductive layer 52 is electrically connected to the lead frame 62 through an adhesive layer 62a. The adhesive layer 32a and 62a can be, for example, a solder or a silver paste.

A plurality of the first wirings 41 and a plurality of the second wirings 42 can be provided and electrically connected to the center portions and the outer edge portions of first coils 21 and second coils 22.

In FIG. 3, the first semiconductor chip 31 and the second semiconductor chip 32 receives an electrical signal at the lower surface (the surface facing the negative direction of the Z direction). An electrical signal is transmitted in a direction from the lead frame 61 to the first wiring 41 through the first semiconductor chip 31 or in the opposite direction thereof. For example, the first semiconductor chip 31 processes the electrical signal input via a lead frame 61, generates electrical signals corresponding to the center portion and the outer edge portion of the first coil 21, and outputs the generated electrical signals to the first wirings 41. In addition, the second semiconductor chip 32 receives the electrical signal from each of the center portion and the outer edge portion of the second coil 22 through the second wiring 42, processes the received electrical signal, and then outputs the processed electrical signal to lead frame 62.

The first semiconductor chip 31 and the first coil 21 are electrically connected through the first wirings 41 provided in the substrate 10. The first wiring 41 extends in the second rigid substrate 13 and the first flexible printed circuit 12 from an upper surface of the second rigid substrate 13, and reaches the first rigid substrate 11 through a lower surface of the first flexible printed circuit 12. The first wiring 41 may be provided between the upper surface of the second rigid substrate 13 and the lower surface of the first flexible printed circuit 12, for example, along the Z direction. The first wiring 41 extends in an XY plane in the first rigid substrate 11 to reach a lower portion of the first coil 21, then extends in the Z direction to be connected to the first coil 21.

Hereinabove, the example of a basic shape of a first wiring 41 is described. However, the shape of the first wiring 41 is not limited to this example. In the first wiring 41, as the proportion of the portion extending in the direction along the Z direction increases, the deterioration in characteristics caused by interference between a magnetic field generated from the first coil 21 and a magnetic field generated from the periphery of the first wiring 41 can be reduced, which is desirable.

The second coil 22 and the second semiconductor chip 32 are electrically connected through the second wiring 42. The second wiring 42 extends from the second coil 22 and extends in the second rigid substrate 13 in the positive Z direction through the upper surface of the second rigid substrate 13. Next, the second wiring 42 extends in an XY plane in the second rigid substrate 13. Finally, the second wiring 42 extends in the second rigid substrate 13 in the Z direction and reaches the upper surface of the second rigid substrate 13. Hereinabove, an example of a basic shape of the second wiring 42 is described. However, the shape of the second wiring 42 is not limited to this example. In the second wiring 42, as the proportion of the portion extending in the direction along the Z direction increases, the deterioration in characteristics caused by interference between a magnetic field passing through the second coil 22 and a magnetic field generated from the periphery of the second wiring 42 can be reduced, which is desirable.

In the first wiring 41 and the second wiring 42, the portion provided along the Z direction can be formed, for example, by drilling in the substrate 10 along the Z direction to form a via hole and then embedding (filling) a conductive material inside the via hole. In addition, in the first wiring 41 and the second wiring 42, the portion provided in the XY plane can be obtained by allowing the first rigid substrate 11 or the second rigid substrate 13 to have a multi-layer structure and forming a wiring layer including a conductive material.

The operation of the isolator 100 will be described again with reference to FIG. 3. A case where the lead frame 61 is an input terminal and the lead frame 62 is an output terminal will be described. The lead frame 61 provides an electrical signal to the first semiconductor chip 31 through the conductive layer 51. The first semiconductor chip 31 executes a predetermined process on the received input signal and transmits the processed signal to the first wiring 41. The first wiring 41 includes a portion connected to the center portion of the first coil 21 and a portion connected to the outer edge portion of the first coil 21.

The first coil 21 receives a signal from the first semiconductor chip 31. A current flows through the first coil 21 corresponding to the input signal received by the lead frame 61. The current flowing through the first coil 21 generates a magnetic field in the Z direction in FIG. 3.

When the magnetic field reaches the second coil 22 that is electrically insulated from the first coil 21 through the first flexible printed circuit 12, a current flows through the second coil 22 by electromagnetic induction. The current flowing through the second coil 22 passes through the second wiring 42 as an electrical signal and reaches the second semiconductor chip 32. The second semiconductor chip 32 executes a predetermined process on the received electrical signal and outputs the processed electrical signal to the lead frame 62 through the conductive layer 52.

Hereinafter, an example of a method of manufacturing the isolator 100 according to the first embodiment will be described. First, the first coil 21, the second coil 22, the first wiring 41, the second wiring 42, and the conductive layers 51 and 52 are formed on the substrate 10. Next, the first semiconductor chip 31 and the second semiconductor chip 32 are mounted with the adhesive layers 31a and 32a. In addition, the lead frames 61 and 62 are provided through the adhesive layers 61a and 62a. The lead frames 61 and 62 are sealed with the resin portion 70 except for end portions functioning as input and output terminals.

Next, an example of the structure of the first flexible printed circuit 12 will be described with reference to FIG. 4. The first flexible printed circuit 12 includes a base 12a (base film) and an insulator 12b (insulator layer). The base 12a is, for example, a film of insulating material such as a polyimide or a liquid crystal polymer. The insulator 12b can be or include, for example, a thermosetting resin such as a “prepreg.” The insulator 12b can be on the upper and lower surfaces of the base 12a.

The first coil 21 is on a lower surface of the base 12a. The second coil 22 is on an upper surface of the base 12a. The insulator 12b is provided on both of the upper and lower surfaces of the base 12a to respectively cover the first coil 21 and the second coil 22. Here, the insulator 12b is with a thickness greater than or equal to a thickness of the first coil 21 or the second coil 22 in the Z direction. Upper and lower surfaces of the first flexible printed circuit 12 can be kept flat by the presence of insulator 12b.

The substrate 10 is then formed by putting the first rigid substrate 11 and the second rigid substrate 13 on upper and lower portions of the first flexible printed circuit 12 as illustrated in FIG. 4.

With the isolator 100 according to the first embodiment, by reducing deformation of the first flexible printed circuit 12 when the lead frames 61 and 62, the first semiconductor chip 31, or the second semiconductor chip 32 are mounted on the substrate 10, deformation of the substrate 10 can be reduced, and the reliability of the isolator 100 can be improved. In this case, the deformation of the substrate 10 includes warping, bending, or displacement of the substrate 10.

For example, when the first semiconductor chip 31 is placed, the substrate 10 locally receives a force in the Z direction. The reason for this is that the first semiconductor chip 31 positioned in the positive Z direction when seen from the substrate 10 needs to be bonded to the substrate 10 by being pressed in the negative Z direction. That is, when the first semiconductor chip 31 is mounted on the substrate 10, stress is applied to the substrate 10.

Here, for comparison, a case where a semiconductor chip is mounted on a substrate including only a flexible printed circuit board will be described. In a substrate including only a flexible printed circuit board, the flexible printed circuit board may be bent due to stress applied during the mounting of a semiconductor chip or the like to the flexible printed circuit. Further, a substrate including only a flexible printed circuit board is lighter than a substrate including a rigid substrate and thus displacement is more likely to occur in the lighter substrate. That is, in a substrate including only a flexible printed circuit board, unintended bending or mounting displacement may occur.

On the other hand, according to the first embodiment, the substrate 10 has a stacked structure including a flexible printed circuit board and one or more rigid substrate, the stiffness of the stacked rigid substrate(s) is higher than that of the flexible printed circuit board, and thus possibility for deformation of the flexible printed circuit board is reduced. Accordingly, deformation of the substrate 10 is reduced, and the reliability can be improved.

The substrate 10 includes the first rigid substrate 11 and the second rigid substrate 13. For example, the first flexible printed circuit 12 (a FPC board) is interposed between these rigid substrates in the Z direction. Accordingly, to deform the substrate 10, a higher stress is required to deform the two rigid substrates. Deformation of the substrate 10 can be further reduced.

By reducing deformation of the first flexible printed circuit 12, improving mounting stability, and reducing breakdown and defects caused by deformation of the substrate 10, the device (manufacturing) yield can be improved. Here, the mounting stability being high represents that, for example, when a semiconductor chip or a lead frame is mounted on to the substrate 10, the structure of the substrate 10 can be stably maintained without being deformed by the process. According to the first embodiment, by reducing deformation of the substrate 10, the reliability of the isolator 100 can be improved.

Electrical connection can be more reliably maintained by reducing deformation (flexibility) of the substrate 10, and high efficiency of magnetic coupling between the coils can likewise be maintained by reducing deformation of the substrate 10. Accordingly, signal loss in transmission can be reduced, and performance of signal transmission can be improved.

In addition, with the isolator 100 according to the first embodiment, the first wirings 41 and the second wirings 42 are implemented as the internal wiring of the substrate 10, and separate electrical connection by a bonding wire or the like is not required. Accordingly, a wire bonding step can be skipped, the manufacturing efficiency can be improved, and the manufacturing process can be shortened.

Further, with the isolator 100, by mounting the first coil 21 and the second coil 22 on the first flexible printed circuit 12, the distance between the first coil 21 and the second coil 22 in the Z direction can be finely controlled to increase the magnetic coupling constant between coils. As the distance between the first coil 21 and the second coil 22 in the Z direction decreases, the magnetic field generated from the first coil 21 can reach the second coil 22 with reduced loss. That is, the magnetic coupling constant being high indicates that signal transmission loss from the first coil 21 to the second coil 22 will be small. The magnetic coupling constant can be increased by forming a coil on each of the upper and lower surfaces of a flexible printed circuit 12 having a smaller thickness as compared to a case where coils are formed on only rigid substrates.

The first wiring 41 and the second wiring 42 include a portion along the Z direction and a portion provided in the XY plane. In the first wiring 41, focusing on the portion ranging from below the first semiconductor chip 31 to the first rigid substrate 11, the wiring is along the Z direction. Therefore, a magnetic field generated when a current flows is in a direction orthogonal to the Z direction. A magnetic field generated along the Z direction from the first coil 21 and a magnetic field generated when a current flows through the portion along the Z direction of the first wiring 41 are orthogonal to each other. Since the magnetic fields are orthogonal to each other, interference of magnetic fields can be reduced, and deterioration in characteristics relating to noise can be reduced.

The portion of the first wiring 41 or the second wiring 42 provided parallel to the XY plane in the first rigid substrate 11 and the second rigid substrate 13 are spaced from the first coil 21 and the second coil 22 in the Z direction. Since the portions are spaced from the first coil 21 and the second coil 22 in this manner, interference of magnetic fields can be reduced.

Interference of magnetic fields between the coils (the first coil 21 and the second coil 22) and the wirings (the first wiring 41 and the second wiring 42) varies depending on a layout of the wirings and the like. Therefore, when a positional relationship between the coils and the wirings changes depending on deformation of the substrate 10, interference of magnetic fields may be promoted. According to the present embodiment, by reducing deformation of the substrate 10, deterioration in characteristics caused by interference can be reduced.

### First Modification Example of First Embodiment

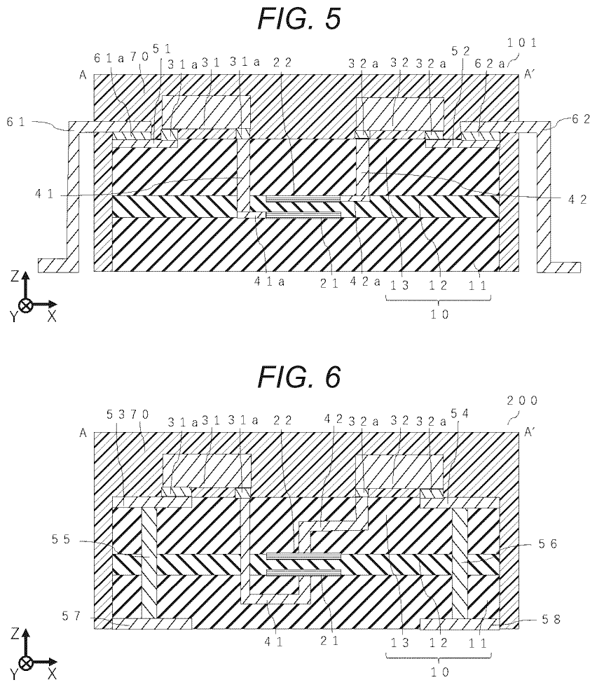

FIG. 5 illustrates a cross-sectional structure of an isolator 101 according to a first modification example of the first embodiment.

The isolator 101 is different from the isolator 100 in the structure for connecting the first semiconductor chip 31 and the first coil 21 and/or the structure for connecting the second semiconductor chip 32 and the second coil 22.

The first wiring 41 includes a first portion 41a formed on the first flexible printed circuit 12. The first portion 41a extends along the lower surface of the first flexible printed circuit 12 and is connected to the first coil 21.

The second wiring 42 includes a first portion 42a formed on the first flexible printed circuit 12. The first portion 42a extends along the upper surface of the first flexible printed circuit 12 and is connected to the second coil 22.

The first portion 41a of the first wiring 41 and the first portion 42a of the second wiring 42 are provided, for example, in the insulator 12b (illustrated in FIG. 4) of the first flexible printed circuit 12. For example, the first portion 41a and the first portion 42a may be formed by adding a step of forming a layer including a conductive material to a step of forming the insulator 12b.

A plurality of the first portions 41a can be provided and can be connected to the center portions and the outer edge portions of the various first coils 21, respectively. A plurality of the first portions 42a can be provided and can be connected to the center portions and the outer edge portions of the second coils 22, respectively.

With the isolator 101, by providing the first portions 41a and 42a on the first flexible printed circuit 12, the wiring length for electrical connection between the semiconductor chip (31 or 32) and the coil (21 or 22) can be reduced.

The electrical connection between semiconductor chip and coil can be established through a shorter total wiring length. Therefore, a magnetic field generated when a current flows through the connecting wiring can be reduced. Accordingly, deterioration in characteristics caused by interference of magnetic fields can be reduced. Loss of signal in transmission between the first coil 21 and the second coil 22 can be further reduced.

### Second Embodiment

FIG. 6 illustrates a cross-sectional structure of an isolator 200 according to a second embodiment.

The isolator 200 according to the second embodiment includes back electrodes 57 and 58. The back electrode 57 is electrically connected to the first semiconductor chip 31 (the adhesive layer 31a provided below the first semiconductor chip 31) through a conductive layer 53 provided below the first semiconductor chip 31 and a through-conductive region 55 provided between the conductive layer 53 and the back electrode 57. The back electrode 57 is, for example, an input terminal.

The back electrode 58 is electrically connected to the second semiconductor chip 32 (the adhesive layer 32a provided below the second semiconductor chip 32) through a conductive layer 54 provided below the second semiconductor chip 32 and a through-conductive region 56 provided between the conductive layer 54 and the back electrode 58. The back electrode 58 is, for example, an output terminal.

The conductive layers 53 and 54 are formed on the second rigid substrate 13. The back electrodes 57 and 58 are formed on the first rigid substrate 11. The conductive layers 53 and 54 and the back electrodes 57 and 58 can be obtained, for example, by forming a layer including a conductive material on a rigid substrate having a multi-layer structure.

The through-conductive regions 55 and 56 penetrate the first rigid substrate 11, the first flexible printed circuit 12, and the second rigid substrate 13 in the Z direction. The through-conductive regions 55 and 56 are formed, for example, by drilling in the Z direction to form a via hole and then embedding a conductive material in the via hole.

With the isolator 200 to the second embodiment, an input terminal and an output terminal can be formed by having exposed electrodes on the back surface of the isolator 200. A package that is applicable to a configuration of mounting different from that in the isolator 100 according to the first embodiment can be provided. Not only the isolator 100 or the isolator 200 but also various structures of terminals of packages can be adopted.

### Third Embodiment

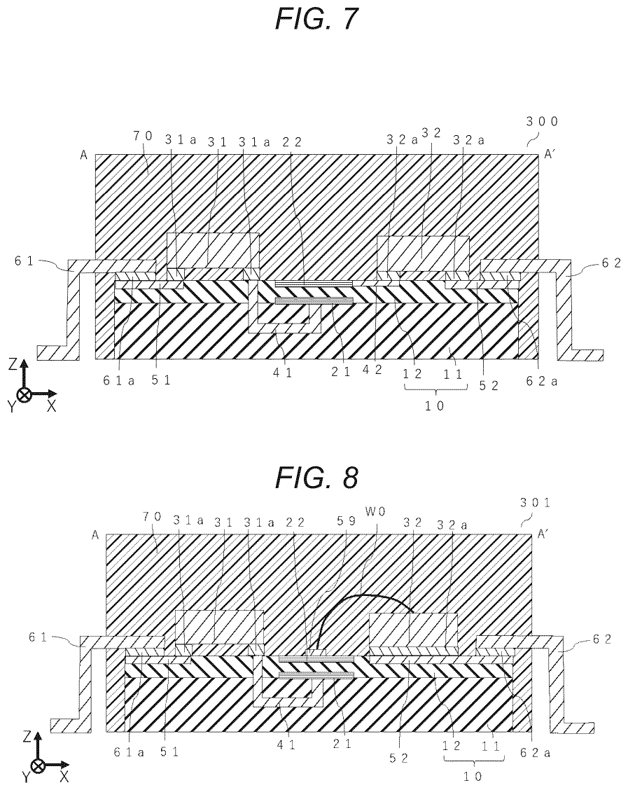

FIG. 7 illustrates a cross-sectional structure of an isolator 300 according to a third embodiment.

The substrate 10 in the isolator 300 has only a two-layer structure including a first rigid substrate 11 and a first flexible printed circuit 12. The first rigid substrate 11, and the first flexible printed circuit 12. The first flexible printed circuit 12 is provided on the first rigid substrate 11.

The conductive layers 51 and 52 are formed on the upper surface of the first flexible printed circuit 12. The conductive layers 51 and 52 are formed, for example, in the insulator 12b (illustrated in FIG. 4) of the first flexible printed circuit 12.

The first semiconductor chip 31 and the second semiconductor chip 32 are provided on the first flexible printed circuit 12 through the adhesive layers 31a and 32a. In addition, the lead frames 61 and 62 are provided on the conductive layers 51 and 52 through the adhesive layers 61a and 62a. The lead frame 61 is, for example, an input terminal, and the lead frame 62 is, for example, an output terminal.

The first wiring 41 extends in the first flexible printed circuit 12 and the first rigid substrate 11 and connects the adhesive layer 31a below the first semiconductor chip 31 to the first coil 21. The shape of the first wiring 41 is not limited to the shape illustrated in FIG. 7 and, in other examples, the first wiring 41 may be formed of only in the first flexible printed circuit 12 rather than with a portion in the first rigid substrate 11.

The second wiring 42 connected to the second coil 22 is formed in the insulator 12b (illustrated in FIG. 4) of the first flexible printed circuit 12. The second wiring 42 extends along the upper surface of the first flexible printed circuit 12 and is connected to the second coil 22. The plurality of second wirings 42 connected to the center portions and the outer edge portions of the second coils 22, respectively, are connected to the second semiconductor chip 32 through the adhesive layer 32a.

With the isolator 300 according to the third embodiment, the substrate 10 has a two-layer structure, and thus the package can be made smaller than with a three-layer structure. The substrate 10 includes the first rigid substrate 11 and the first flexible printed circuit 12. As compared to the isolator 100 according to the first embodiment, the thickness of the substrate 10 can be reduced by the thickness corresponding to the second rigid substrate 13. Accordingly, the package can be made smaller.

The substrate 10 still includes first rigid substrate 11, and thus can still reduce deformation of the first flexible printed circuit 12. The reliability of the isolator 300 can be improved as compared to only a design with only a FCP board.

In FIG. 7, electrical connection between the second coil 22 and the second semiconductor chip 32 does not require a wire bonding step and this can reduce manufacturing steps.

In addition, the wiring length of the first wiring 41 in the third embodiment can be reduced as compared to the first embodiment. Therefore, deterioration in characteristics relating to signal transmission caused by interference can be reduced. The second wiring 42 extending in the Z direction (illustrated in FIG. 3) is not required, and interference of magnetic fields can be further reduced.

### First Modification Example of Third Embodiment

An isolator 301 according to a first modification example of the third embodiment will be described with reference to FIG. 8.

FIG. 8 illustrates an example where electrodes are provided such that the second semiconductor chip 32 transmits an electrical signal in a direction from the upper surface to the lower surface.

The first coil 21 is formed on the lower surface of the first flexible printed circuit 12, and the second coil 22 is formed on the upper surface. An electrode pad 59 electrically connected to the second coil 22 is provided on the second coil 22. A wire W0 connects the electrode pad 59 to an upper surface of the second semiconductor chip 32. The wire W0 is connected to the electrode pad 59 by wire bonding.

A plurality of the electrode pads 59 are provided, for example, arrayed in the XY plane and are connected to the second coils 22, and a plurality of the wires W0 are also correspondingly provided.

With the isolator 301 according to the first modification example of the third embodiment, when electrical connection between the upper surface of the semiconductor chip (for example, the second semiconductor chip 32) and the coil (for example, the second coil 22) is established by wire bonding, deformation of the substrate 10 can be reduced. The substrate 10 includes the first rigid substrate 11 below the first flexible printed circuit 12, and thus can have reduced deformation of the first flexible printed circuit 12. The reliability of the isolator 301 can be improved.

### Fourth Embodiment

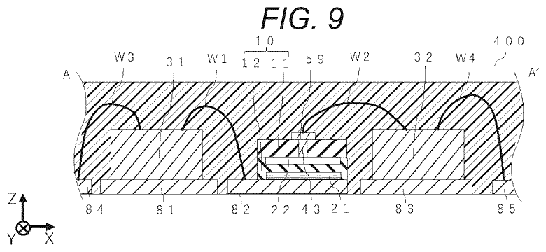

FIG. 9 illustrates a cross-sectional structure of an isolator 400 according to a fourth embodiment.

The isolator 400 includes a first semiconductor chip on a first die pad 81. The substrate 10 is provided on a second die pad 82. The second semiconductor chip 32 is provided on a third die pad 83. The first die pad 81, the second die pad 82, and the third die pad 83 are spaced from each other in the X direction.

The first semiconductor chip 31 includes electrodes on its upper surface and, while the first semiconductor chip 31 is in contact with the first die pad 81, it is electrically insulated from the first die pad 81. The second semiconductor chip 32 includes electrodes on its upper surface and, while the second semiconductor chip is in contact with the third die pad 83, it is electrically insulated from the third die pad 83.

A wiring including a coil is provided in the substrate 10 and a part of this wiring is electrically connected to the second die pad 82.

The first semiconductor chip 31 and the second die pad 82 are electrically connected through a wire W1. The wire W1 is in contact with an upper surface of the first semiconductor chip 31 and an upper surface of the second die pad 82. The substrate 10 and the second semiconductor chip 32 are electrically connected through a wire W2.

The substrate 10 has a two-layer structure with a first rigid substrate 11 and a first flexible printed circuit 12. The first rigid substrate 11. The first flexible printed circuit 12. In the example illustrated in FIG. 9, the first rigid substrate 11 is provided above the first flexible printed circuit 12.

The first coil 21 and the second coil 22 are provided in the first flexible printed circuit 12. The internal structure of the first flexible printed circuit 12 can be the same as illustrated in FIG. 4. The first coil 21 is provided on the lower surface of the first flexible printed circuit 12, and the second coil 22 is provided on the upper surface of the first flexible printed circuit 12. The first coil 21 is electrically connected to the second die pad 82. The second coil 22 is electrically insulated from the first coil 21.

A third wiring 43 connected to the second coil 22 penetrates into the first rigid substrate 11 in the Z direction. The third wiring 43 is connected to the electrode pad 59 provided on the upper surface of the first rigid substrate 11. The wire W2 is connected to the electrode pad 59.

The isolator 400 includes external terminals 84 and 85. The external terminals 84 and 85 are spaced from the first die pad 81, the second die pad 82, and the third die pad 83. The external terminal 84 is, for example, an input terminal. The external terminal 85 is, for example, an output terminal.

The external terminal 84 and the first semiconductor chip 31 are electrically connected through a wire W3. The external terminal 85 and the second semiconductor chip 32 are electrically connected through a wire W4. That is, the first semiconductor chip 31 includes a plurality of electrodes on the upper surface, one of the electrodes is connected to the second die pad 82 through a wire W1, and another electrode is connected to the external terminal 84 through a wire W3. That is, the second semiconductor chip 32 includes a plurality of electrodes on the upper surface, one of the electrodes is connected to the electrode pad 59 through a wire W2, and another electrode is connected to the external terminal 85 through a wire W4.

Next, an operation of the isolator 400 will be described. An example where the external terminal 84 is an input terminal and the external terminal 85 is an output terminal will be described.

An electrical signal input to the external terminal 84 reaches the first semiconductor chip 31 through the wire W3. The first semiconductor chip 31 executes a predetermined process on the received electrical signal and outputs the processed electrical signal to the wire W1. The signal output from the first semiconductor chip 31 reaches the first coil 21 from the wire W1 through the second die pad 82.

The first coil 21 generates a magnetic field based on the received electrical signal. For example, in FIG. 9, a magnetic field in the Z direction is generated. The magnetic field in the Z direction pass through the second coil 22 spaced from the first coil 21 in the Z direction. A current flows through the second coil 22 by electromagnetic induction. A signal is transmitted between the first coil 21 and the second coil 22 through the magnetic field.

The signal transmitted to the second coil 22 flows to the wire W2 through the third wiring 43 and the electrode pad 59. The signal is transmitted to the second semiconductor chip 32 through the wire W2. The second semiconductor chip 32 executes a predetermined process on the signal and outputs the processed signal to the wire W4. The signal transmitted to the external terminal 85 from the wire W4 is an output signal.

With the isolator 400 according fourth embodiment, while thinning the substrate 10 to make the package smaller, deformation of the first flexible printed circuit 12 can be reduced, and the reliability can be improved.

The substrate 10 has a two-layer structure where the first rigid substrate 11 and the first flexible printed circuit 12 are stacked. As compared to the isolator 100 according to the first embodiment, the thickness of the substrate 10 can be reduced. By reducing the thickness of the substrate 10, the package can be made smaller.

The first rigid substrate 11 is rigid, so when the wire W2 or the like is formed by wire bonding, deformation of the first flexible printed circuit 12 can be reduced. The reliability of the isolator 400 can be improved.

In some examples, the first rigid substrate 11 may have a smaller planar area than the first flexible printed circuit 12. The electrode pad 59 can be provided on the first rigid substrate 11. Stress is applied to the substrate 10 in the wire bonding step of connecting the wire W2 to the electrode pad 59. However, since the first rigid substrate 11 can be positioned at least below the electrode pad 59, stress applied during mounting of the wire W2 can be dispersed to the first rigid substrate 11. By reducing the amount of a material forming the first rigid substrate 11, the manufacturing cost can be reduced.

In at least one of the embodiments described above, the substrate 10 has a structure of at least two layers including a rigid substrate layer and a flexible printed circuit board layer, and deformation of a first flexible printed circuit 12 where the first coil 21 and the second coil are disposed can be reduced. By improving the mounting stability and reducing breakdown and defects, the reliability of an isolator device can be improved. In addition, by forming a coil on both the upper and lower surfaces of the first flexible printed circuit 12, magnetic coupling coefficient can be increased by reducing the distance between coils, and performance relating to signal transmission can be improved. Further, regarding the structure for connecting the first semiconductor chip 31 and the first coil 21 or the second semiconductor chip and the second coil 22, deterioration in characteristics relating to signal transmission caused by interference from connecting wiring can be reduced.

Hereinabove, an isolator using a coil has been described. However, the embodiments are also applicable to an isolator using a capacitor.

In addition, the elements in the various above-described embodiments may be combined with one another as long as these combinations are technically possible, and such combinations are to be considered as within the scope of the present disclosure. In addition, those skilled in the art can conceive various changes and modifications from the concepts of the various example embodiments, and it is understood that these changes and modifications are also within the scope of the present disclosure.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An isolator device, comprising:
a first rigid substrate;
a flexible printed circuit board stacked on the first rigid substrate in a first direction;
a first coil in the flexible printed circuit board;
a second coil in the flexible printed circuit board, the second coil spaced from and aligned with the first coil in the first direction;
a first semiconductor chip connected to the first coil by a first wiring; and
a second semiconductor chip connected to the second coil by a second wiring.

2. The isolator device according to claim 1, wherein the flexible printed circuit board is between the first rigid substrate and the first and second semiconductor chips in the first direction.

3. The isolator device according to claim 2, wherein the first wiring extends through the flexible printed circuit board in the first direction.

4. The isolator device according to claim 2, further comprising:
a second rigid substrate stacked on the flexible printed circuit board, wherein
the flexible printed circuit board is between the first rigid substrate and the second rigid substrate in the first direction.

5. The isolator device according to claim 4, wherein the first wiring extends through the second rigid substrate in the first direction.

6. The isolator device according to claim 5, wherein the second wiring extends through the second rigid substrate in the first direction.

7. The isolator device according to claim 6, wherein the first wiring extends in the first direction through a portion of the first rigid substrate and in a second direction parallel to an upper surface of the first rigid substrate.

8. The isolator device according to claim 5, wherein a first portion of the first wiring extends in a second direction parallel to a surface of the flexible printed circuit board along the surface of the flexible printed circuit board and connects to the first coil.

9. The isolator device according to claim 1, further comprising:
a resin covering the first semiconductor chip and the second semiconductor chip;
a first lead frame including a portion extending out of the resin, the first lead frame electrically connected to the first semiconductor chip; and
a second lead frame including a portion extending out of the resin, the second lead frame electrically connected to the second semiconductor chip.

10. The isolator device according to claim 1, further comprising:
a resin covering the first semiconductor chip and the second semiconductor chip;
a first back electrode on a backside surface of the first rigid substrate;
a second back electrode on the backside surface of the first rigid substrate;
a first through-conductive region extending in the first direction through the flexible printed circuit board and the first rigid substrate and electrically connected to the first back electrode;
a second through-conductive region extending in the first direction through the flexible printed circuit board and the first rigid substrate and electrically connected to the second back electrode;
a first conductive layer electrically connecting the first semiconductor chip to the first-through conductive region; and
a second conductive layer electrically connecting the second semiconductor chip to the second-through conductive region.

11. The isolator device according to claim 1, wherein the flexible printed circuit board comprises:
a base film,
a first insulator layer on a first surface of the base film, and
a second insulator layer on a second surface of the base film.

12. The isolator device according to claim 11, wherein
the first coil is on the first surface of the base film,
the second coil is on the second surface of the base film,
the thickness of the first insulator layer on the first surface is greater than or equal to the thickness of the first coil in the first direction, and
the thickness of the second insulator layer on the second surface is greater than or equal to the thickness of the second coil in the first direction.

13. The isolator device according to claim 11, wherein
the base film is polyimide,
the first insulator layer is a thermosetting resin, and
the second insulator layer is a thermosetting resin.

14. The isolator device according to claim 1, further comprising:
a first die pad;
a second die pad spaced from the first die pad in a second direction intersecting the first direction; and
a third die pad between the first and second die pads in the second direction, wherein
the first semiconductor chip is on the first die pad,
the second semiconductor chip is on the second die pad, and
the first rigid substrate and the flexible printed circuit board are on the third die pad.

15. An isolator device, comprising:
a first die pad;
a first semiconductor chip on the first die pad;
a second die pad spaced from the first die pad;
a substrate on the second die pad and including a first rigid substrate and a flexible printed circuit board stacked on the first rigid substrate in a first direction;
a first coil in the flexible printed circuit board;
a second coil in the flexible printed circuit board, the second coil spaced from and aligned with the first coil in the first direction;
an electrode pad on an upper surface of substrate and electrically connected to the second coil;
a third die pad spaced from the first die pad and the second die pad in a second direction intersecting the first direction;
a second semiconductor chip on the third die pad;
a first wire electrically connecting the first semiconductor chip to the second die pad; and
a second wire electrically connecting the electrode pad to the second semiconductor chip.

16. The isolator device according to claim 15, wherein
the flexible printed circuit board comprises:
a base film,
a first insulator layer on a first surface of the base film, and
a second insulator layer on a second surface of the base film,
the first coil is on the first surface of the base film, and
the second coil is on the second surface of the base film.

17. The isolator device according to claim 16, wherein
the base film is polyimide,
the first insulator layer is a thermosetting resin, and
the second insulator layer is a thermosetting resin.

18. An isolator device, comprising:
a first rigid substrate;
a flexible circuit substrate stacked on the first rigid substrate in a first direction;
a second rigid substrate stacked on the flexible circuit substrate;
a first coil in the flexible circuit substrate;
a second coil in the flexible circuit substrate, the second coil spaced from and aligned with the first coil in the first direction;
a first semiconductor chip mounted on the second rigid substrate and connected to the first coil by a first wiring with at least a portion of the first wiring extending in the second rigid substrate; and
a second semiconductor chip mounted on the second rigid substrate and connected to the second coil by a second wiring with at least a portion of the second wiring extending in the second rigid substrate.

19. The isolator device according to claim 18, further comprising:
a resin covering the first and second semiconductor chips and contacting the second rigid substrate.

20. The isolator device according to claim 18, wherein
the flexible circuit substrate comprises:
a base film,
a first insulator layer on a first surface of the base film, and
a second insulator layer on a second surface of the base film,
the first coil is on the first surface of the base film, and
the second coil is on the second surface of the base film.
